(19) United States
(12) Patent Application Publication
(10) Pub. No.: US 2026/0068095 A1
(43) Pub. Date: Mar. 5, 2026

(54) HEAT DISSIPATION MODULE AND PROJECTION DEVICE

(71) Applicant: Coretronic Corporation, Hsin-Chu (TW)

(72) Inventors: Ken-Teng PENG, Hsin-Chu (TW); Wei-Hao CHEN, Hsin-Chu (TW)

(21) Appl. No.: 19/256,171

(22) Filed: Jul. 1, 2025

(30) Foreign Application Priority Data
Aug. 30, 2024 (CN) 2024112147068

(51) Int. Cl. H05K 7/20; G03B 21/16

(52) U.S. Cl. CPC H05K 7/2039; G03B 21/16

(57) ABSTRACT

A heat dissipation module is provided and includes an elastic component, a heat conduction component, a TEC chip and a heat dissipation component. The elastic component includes a body where the heat conduction component is disposed and at least two slab parts extending outward from the body. The TEC chip has a first surface thermally connected on the heat conduction component and a second surface thermally connected on the heat dissipation component. The heat dissipation component is fixed to the slab parts. The orthographic projection of the body on the TEC chip overlaps the first surface, and the area of the orthographic projection of the body on the TEC chip is less than or equal to the area of the first surface, and thus the elastic force which is generated from the body is applied to the inner side of the TEC chip.

### CROSS REFERENCE TO RELATED APPLICATION

This application claims the priority benefit of Chinese Patent Application Serial Number 2024112147068, filed on Aug. 30, 2024, the full disclosure of which is incorporated herein by reference.

### BACKGROUND

### Technical Field

The present disclosure is related to the field of heat dissipation and optics, and is particularly related to a heat dissipation module and a projection device.

### Related Art

The image formation principle of a projection device is that an illumination light beam generated by a light source is converted to an image light beam by a light valve and the image beam is projected onto a screen or a wall by a lens to form a projecting image. In the current technologies, a heat dissipation module needs to be disposed inside the projection device to perform heat dissipation on the light valve because the light valve would generate a large amount of heat during operation.

The conventional configuration of the heat dissipation module is that a thermoelectric cooler chip (TEC chip) and a heat dissipation component are sequentially stacked to be disposed on a copper block and a plurality of spring rivets pass through the heat dissipation component and are fixed to the copper block to tightly fix the TEC chip, the heat dissipation component and the copper block. The copper block would be connected to the light valve so that the heat generated by the light valve may be transferred to the cold side surface of the TEC chip by the copper block, thereby realizing the effect of a uniform temperature. The hot side surface of the TEC chip contacts the heat dissipation component so that the heat generated by the light valve may be transferred from the hot side surface of the TEC chip to the heat dissipation component for the heat dissipation.

However, in the process of fixing the plurality of spring rivets, the heat dissipation component easily slants and compresses the side of the TEC chip to crack the side of the TEC chip because the force from the plurality of spring rivets is not uniform. Thus, it would cause the TEC chip to fail or deteriorate the performance of the TEC chip and influence the effect of the heat dissipation of the conventional heat dissipation module.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the disclosure was acknowledged by a person of ordinary skill in the art.

### SUMMARY

In light of the deficiencies of the current technologies, the object of the present disclosure is to provide a heat dissipation module and a projection device which prevent the side of the TEC chip from compressing to crack and elevate the effect of the heat dissipation by improving the structure of the heat dissipation module.

Other objectives, features and advantages of the present invention will be further understood from the further technological features disclosed by the embodiments of the present invention wherein there are shown and described preferred embodiments of this invention, simply by way of illustration of modes best suited to carry out the invention.

In order to achieve one, one part or all of the objectives, one embodiment of the present disclosure is to facilitate the heat dissipation module configured to be fixed on a plate to include an elastic component, a heat conduction component, a TEC chip and a heat dissipation component. The elastic component includes a body and at least two slab parts, and the at least two slab parts are respectively located on two sides of the body and extend outward from the body. The heat conduction component is disposed on the body of the elastic component. The TEC chip has a first surface and a second surface which are located on the opposite sides of the TEC chip. The first surface of the TEC chip is thermally connected on the heat conduction component. The heat dissipation component is thermally connected on the second surface of the TEC chip and is fixed to the at least two slab parts of the elastic component. The orthographic projection of the body of the elastic component on the TEC chip overlaps the first surface of the TEC chip, and the area of the orthographic projection of the body of the elastic component on the TEC chip is less than or equal to the area of the first surface of the TEC chip. The elastic component, the heat conduction component, the TEC chip and the heat dissipation component are sequentially mounted along a mounting direction so that the elastic component lies in a mounted state, and when the elastic component lies in the mounted state, each of the at least two slab parts of the elastic component provides the body with elastic force toward the heat conduction component.

In order to achieve one, one part or all of the objectives, one embodiment of the present disclosure is to facilitate the projection device to include a light source, a light valve, a lens, a plate and a heat dissipation module. The light source is configured to provide an illumination light beam. The light valve is disposed on the travel path of the illumination light beam and is configured to convert the illumination light beam into an image light beam. The lens is disposed on the travel path of the image light beam and configured to project the image light beam. The plate is connected to the light valve. The heat dissipation module is configured to be fixed on the plate and includes an elastic component, a heat conduction component, a TEC chip and a heat dissipation component. The elastic component includes a body and at least two slab parts, and the at least two slab parts are respectively located on two sides of the body and extend outward from the body. The heat conduction component is disposed on the body of the elastic component and is connected to the light valve. The TEC chip has a first surface and a second surface which are located on the opposite sides of the TEC chip. The first surface of the TEC chip is thermally connected on the heat conduction component. The heat dissipation component is thermally connected on the second surface of the TEC chip and is fixed to the at least two slab parts of the elastic component. The orthographic projection of the body of the elastic component on the TEC chip overlaps the first surface of the TEC chip, and the area of the orthographic projection of the body of the elastic component on the TEC chip is less than or equal to the area of the first surface of the TEC chip. The elastic component, the heat conduction component, the TEC chip and the heat dissipation component are sequentially mounted along a mounting direction so that the elastic component lies in a mounted state, and when the elastic component lies in the mounted state, each of the at least two slab parts of the elastic component provides the body with elastic force toward the heat conduction component.

In the foregoing configuration provided by the present disclosure, the body of the elastic component is disposed under the heat conduction component, and when the elastic component lies in the mounted state, the at least two slab parts of the elastic component would be fixed to the heat dissipation component and are located between the heat dissipation component and the plate, and each of the at least two slab parts provides the body with elastic force toward the heat conduction component. In addition, the orthographic projection of the body of the elastic component on the TEC chip overlaps the first surface of the TEC chip, and the area of the orthographic projection of the body of the elastic component on the TEC chip is less than or equal to the area of the first surface of the TEC chip; hence, the elastic force which is generated from the body is applied to the inner side of the TEC chip. Accordingly, compressing the side of the TEC chip to crack is avoided, thereby realizing the effect of elevating the heat dissipation of the heat dissipation module.

### BRIEF DESCRIPTION OF THE DRAWINGS

FIG. 1 depicts an exploded view diagram of a heat dissipation module and a plate according to one embodiment of the present disclosure.

FIG. 2 and FIG. 3 depict 3D schematic diagrams of a heat dissipation module before mounting and after mounting according to one embodiment of the present disclosure.

FIG. 4 depicts the 3D schematic diagram of the configuration of FIG. 1 after mounting.

FIG. 5 depicts a schematic diagram of an elastic component of a heat dissipation module according to a first embodied aspect of the present disclosure.

FIG. 6 depicts a schematic diagram of an elastic component of a heat dissipation module according to a second embodied aspect of the present disclosure.

FIG. 7 depicts a schematic diagram of an elastic component of a heat dissipation module according to a third embodied aspect of the present disclosure.

FIG. 8 depicts a schematic diagram of an elastic component of a heat dissipation module according to a fourth embodied aspect of the present disclosure.

FIG. 9 depict a schematic diagram of a projection device according to one embodiment of the present disclosure.

### DETAILED DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

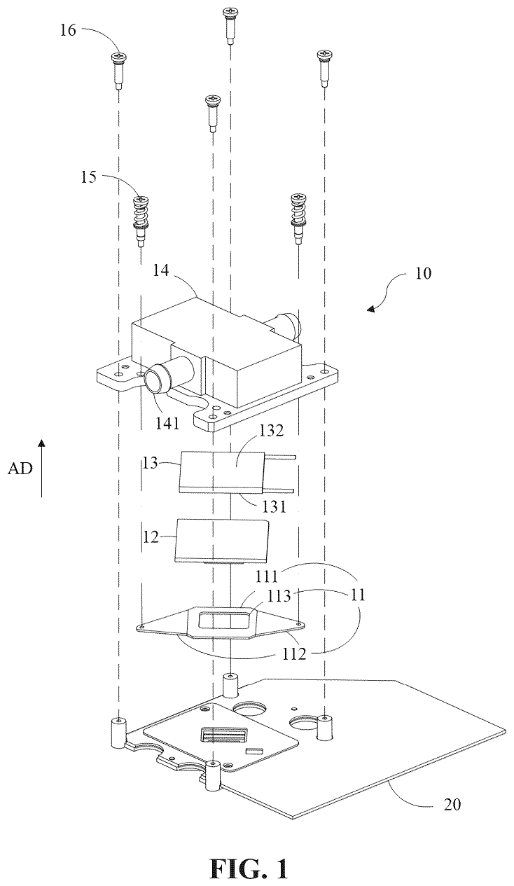

With regard to the heat dissipation module 10 of the embodiments of the present disclosure, please refer to FIG. 1 to FIG. 3. As shown in FIG. 1 to FIG. 3, a heat dissipation module 10 is configured to be fixed on a plate 20. The heat dissipation module 10 includes an elastic component 11, a heat conduction component 12, a TEC chip 13 and a heat dissipation component 14. The elastic component 11, the heat conduction component 12, the TEC chip 13 and the heat dissipation component 14 are sequentially mounted along a mounting direction AD, and after the elastic component 11, the heat conduction component 12, the TEC chip 13 and the heat dissipation component 14 are sequentially mounted along the mounting direction AD, the elastic component 11 lies in a mounted state. The elastic component 11 includes a body 111 and at least two slab parts 112. The at least two slab parts 112 are respectively located on two different sides of the body 111 and extend outward from the body 111; in other words, one end part (without reference numbers) of each of the at least two slab parts 112 extends outward, and the other end part (without reference numbers) of each of the at least two slab parts 112 is connected to the body 111, and the entire end parts of the at least two slab parts 112 extending outward are separate from one another. The heat conduction component 12 has a first face 122 and a second face 123 which are located on the opposite sides of the heat conduction component 12, and the first face 122 of the heat conduction component 12 is disposed on the body 111 of the elastic component 11. The TEC chip 13 has a first surface 131 and a second surface 132 which are located on the opposite sides of the TEC chip 13, and the first surface 131 of the TEC chip 13 is thermally connected on the second face 123 of the heat conduction component 12. The heat dissipation component 14 is thermally connected on the second face 132 of the TEC chip 13 and is fixed to the at least two slab parts 112 of the elastic component 11. After mounting the elastic component 11, the heat conduction component 12, the TEC chip 13 and the heat dissipation component 14 is complete, the body 111 of the elastic component 11, the first face 122 of the heat conduction component 12, the second face 123 of the heat conduction component 12, the first surface 131 of the TEC chip 13, the second surface 132 of the TEC chip 13 and the heat dissipation component 14 are sequentially arranged along the mounting direction AD. The orthographic projection of the body 111 of the elastic component 11 on the TEC chip 13 overlaps the first surface 131 of the TEC chip 13, and the area of the orthographic projection of the body 111 of the elastic component 11 on the TEC chip 13 is less than or equal to the area of the first surface 131 of the TEC chip 13, wherein the orthographic projection of the body 111 of the elastic component 11 on the TEC chip 13 is the projection scope of the body 111 on the first surface 131 of the TEC chip 13 along the mounting direction AD. When the elastic component 11 lies in the mounted state, the at least two slab parts 112 of the elastic component 11 are fixed to the heat dissipation component 14, and each of the at least two slab parts 112 provides the body 111 with elastic force F toward the heat conduction component 12.

Hence, in the heat dissipation module 10 of the present disclosure, the body 111 of the elastic component 11 is disposed under the heat conduction component 12, and when the elastic component 11 lies in the mounted state, the at least two slab parts 112 of the elastic component would be fixed to the heat dissipation component 14 and are located between the heat dissipation component 14 and the plate 20, and each of the at least two slab 112 parts provides the body 111 with the elastic force F toward the heat conduction component 12. In addition, the orthographic projection of the body 111 of the elastic component 11 on the TEC chip 13 overlaps the first surface 131 of the TEC chip 13, and the area of the orthographic projection of the body 111 of the elastic component 11 on the TEC chip 13 is less than or equal to the area of the first surface 131 of the TEC chip 13, so that the elastic force which is generated from the body is applied to the inner side of the TEC chip 13. Accordingly, compressing the side of the TEC chip 13 to crack is avoided, thereby realizing the effect of elevating the heat dissipation of the heat dissipation module 10.

As shown in FIG. 1 to FIG. 3, in the present embodiment, the elastic component 11, the heat conduction component 12, the TEC chip 13 and the heat dissipation component 14 are sequentially stacked to be disposed from the bottom to the top along the mounting direction AD. Therefore, the orthographic projection of the body 111 of the elastic component 11 on the TEC chip 13 along the mounting direction AD overlaps the first surface 131 of the TEC chip 13, and the area of the orthographic projection of the body 111 of the elastic component 11 on the TEC chip 13 along the mounting direction AD is less than or equal to the area of the first surface 131 of the TEC chip 13. In other words, the orthographic projection scope of the body 111 totally lies within the scope of the first surface 131 of the TEC chip 13 or the orthographic projection scope of the body 111 is equal to the scope of the first surface 131 of the TEC chip 13.

In the present embodiment, the heat dissipation module 10 further includes at least two first securing components 15. Each of the at least two slab parts 112 of the elastic component 11 extends outward from the body 111, the shape of each of the at least two slab parts 112 is a triangle for example, and the end part of each of the at least two slab parts 112 (one end of the triangle) extends outward and is be relatively far away from the body 111. The at least two first securing components 15 face down (e.g., opposite to the mounting direction AD) to pass through the heat dissipation component 14 and are fastened to the end parts of the at least two slab parts 112 of the elastic component 11 to fix the heat dissipation component 14 and the at least two slab parts 112 of the elastic component 11. The at least two first securing components 15 fix the end parts of the at least two slab parts 112 to the heat dissipation component 14 so that the elastic component 11 lies in the mounted state. In the present embodiment, the number of the at least two first securing components 15 corresponds to the number of the at least two slab parts 112 of the elastic component 11.

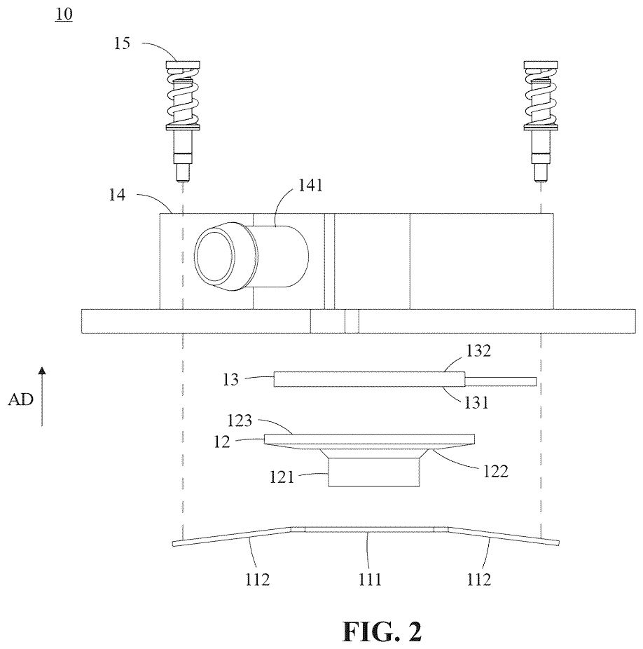

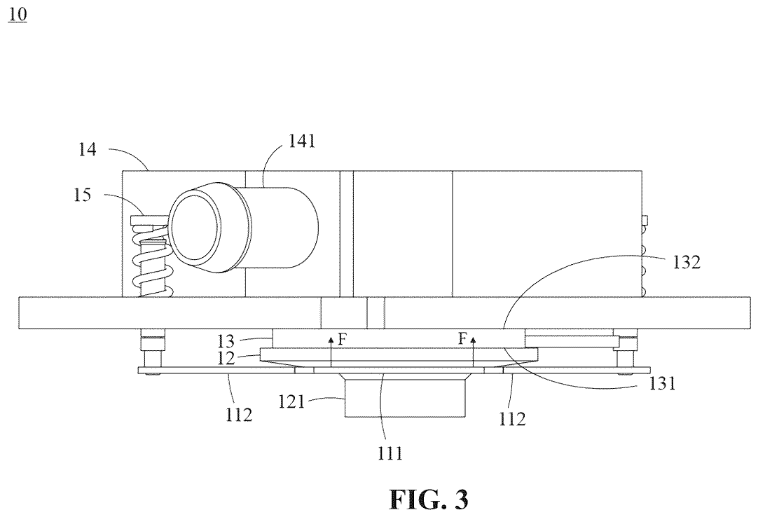

In order to elaborate the change of the mounted state of the elastic component 11 in the present embodiment, please refer to FIG. 2 and FIG. 3. In the present embodiment, FIG. 2 illustrates the non-mounted state of the elastic component 11, and FIG. 3 illustrates the mounted state of the elastic component 11. As shown in FIG. 2, when the at least two first securing components 15 are not fastened to the end parts of the at least two slab parts 112 of the elastic component 11, the elastic component 11 lies in a non-mounted state, and the at least two slab parts 112 respectively extend from the two different sides of the body 111 and slant or bend in the direction far away from the heat conduction component 12 to be shown as curved shapes. For example, there is an included angle between each of the at least two slab parts 112 and the body 111, and the included angle is not 0° or 180°. When the elastic component 11 lies in the non-mounted state, the elastic component 11 is in a static state which does not generate deformation. However, the foregoing descriptions are not to limit the present disclosure, and in the different embodiments, the at least two slab parts 112 may extend outward from the two different sides of the body 111 along a horizontal direction to be shown as a planar shape.

Afterward, as shown in FIG. 3, when the at least two first securing components 15 are fastened to the end parts of the at least two slab parts 112 of the elastic component 11 and fix the end parts of the at least two slab parts 112 to the heat dissipation component 14, the elastic component 11 transforms from the non-mounted state to the mounted state. Thus, each of the at least two slab parts 112 would provide the body 111 with the elastic force F toward the heat conduction component 12 to tightly fix the heat conduction component 12, the TEC chip 13 and the heat dissipation component 14 by the elastic force F.

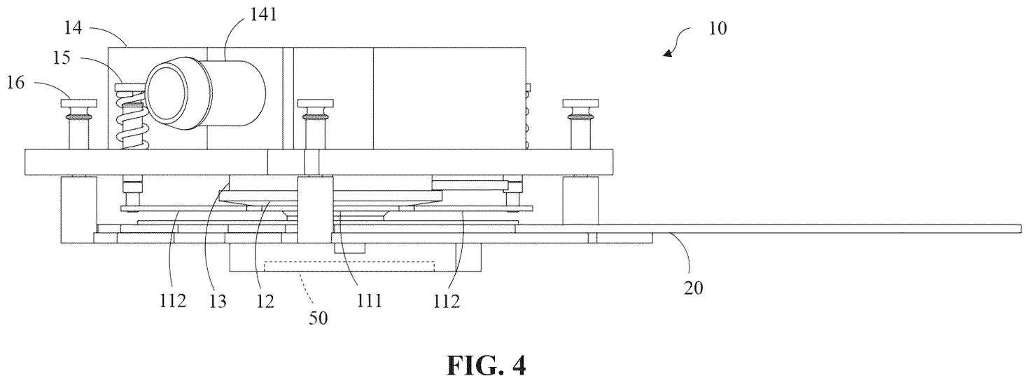

In order to fix the heat dissipation module 10 of the present disclosure to the plate 20, as shown in FIG. 4, the heat dissipation module 10 in the present embodiment may further include at least two second securing components 16. Each of the at least two second securing components 16 face down (e.g., opposite to the mounting direction AD) to pass through the heat dissipation component 14 and are fastened to the plate 20 so that the heat dissipation module 10 and the plate 20 are tightly fixed, the at least two slab parts 112 of the elastic component 11 are located between the heat dissipation component 14 and the plate 20. The at least two second securing components 16 do not directly contact the elastic component 11 to avoid affecting the elastic component 11 to evenly provide the heat conduction component 12 and TEC chip 13 with the elastic force F.

In order to elaborate the detailed structure of the body 111 of the elastic component 11 and the heat conduction component 12, please refer to FIG. 1 to FIG. 4. As shown in FIG. 1 to FIG. 4, the shape of the body 111 of the elastic component 11 is a rectangle frame; the foregoing description are exemplary and is not used to limit the present disclosure. Preferably, the elastic component 11 has an opening 113 passing through the body 111, and the first face 122 of the heat conduction component 12 correspondingly has a protrusion 121; in other words, the protrusion 121 protrudes from the first face 122, wherein the shape (area) of the protrusion 121 matches the shape (area) of the opening 113 or the shape (area) of the protrusion 121 is less than the shape (area) of the opening 113. In the present embodiment, when the elastic component 11, the heat conduction component 12, the TEC chip 13 and the heat dissipation component 14 are sequentially mounted along the mounting direction AD, the protrusion 121 on the first face 122 of the heat conduction component 12 passes through the opening 113 of the body 111 to be thermally connected to a heat generating component which is disposed on the plate 20 so that the TEC chip 13 may cool the heat generating component by the heat conduction component 12. For example, the heat generating component may be a light source or a light valve 50, the light source may be a laser diode (LD) or a light-emitting diode (LED), and the light valve 50 may be a digital micro mirror device (DMD); however, the present disclosure is not limited thereto. The heat generating component may be the component (such as a circuit board or a processor) which generates the heat. In the present embodiment, when the elastic component 11 lies in the mounted state, each of the at least two slab parts 112 provides the frame part (without reference numbers) of the body 111 shown as the rectangle frame with the elastic force F toward the heat conduction component 12.

In the present embodiment, the first surface 131 of the TEC chip 13 is a cold side surface, and the second surface 132 of the TEC chip 13 is a hot side surface. The second face 123 of the heat conduction component 12 is thermally connected to the cold side surface (first surface 131) of the TEC chip 13, and the heat dissipation component 14 is thermally connected to the hot side surface (second surface 132) of the TEC chip 13. When the heat generating component generates a large amount of heat during operation, the cold side surface of the TEC chip 13 may perform heat dissipation on the heat generating component by the heat conduction component 12, and the hot side surface of the TEC chip 13 would transfer the heat generated by the heat generating component to the heat dissipation component 14. Accordingly, cooling the heat generating component is achieved to prevent the heat generating component from damaging due to overheating. For example, the heat dissipation component 14 may be an air cooler with a heat dissipation fin structure or a liquid cooler with a heat pipe structure. If the heat dissipation component 14 is the liquid cooler, cooling fluid may flow in the pipe 141 of the heat dissipation component 14, but the present disclosure is not limited thereto.

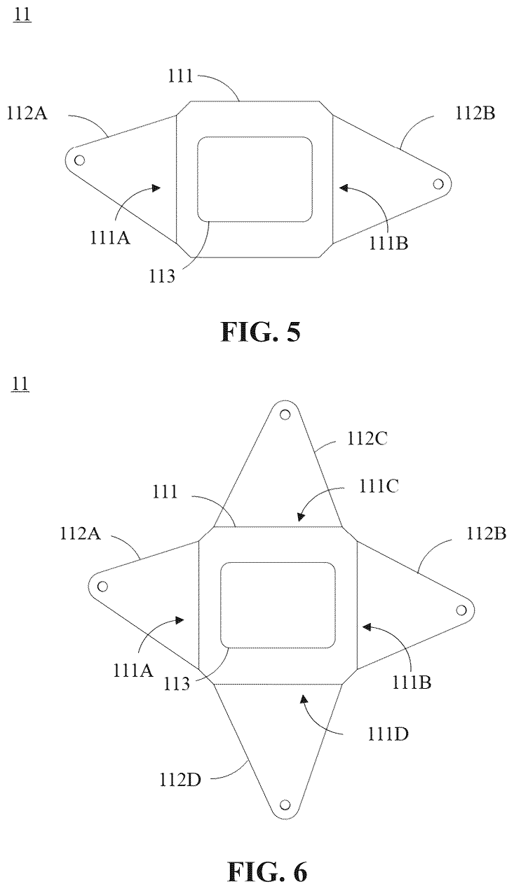

In order to further explain the applied manners of the embodied aspects in the various shapes of the elastic component 11 in the present embodiment, please refer to FIG. 5 which is the first embodied aspect in the shape of the elastic component 11. The two sides of the body 111 are a first side 111A and a second side 111B which are opposite to each other, and the at least two slab parts 112 includes a first slab part 112A and a second slab part 112B. The first slab part 112A and the second slab part 112B respectively extend outward from the first side 111A and the second side 111B of the body 111, and each of the first slab part 112A and the second slab part 112B is a triangle plate.

Please refer to FIG. 6, which is the second embodied aspect in the shape of the elastic component 11. As shown in FIG. 6, the second embodied aspect in the shape of the elastic component 11 is similar to the first embodied aspect in the shape of the elastic component 11, but there are differences between the second embodied aspect in the shape of the elastic component 11 and the first embodied aspect in the shape of the elastic component 11: the body 111 further has a third side 111C and a fourth side 111D which are opposite to each other, the third side 111C is connected between the first side 111A and the second side 111B, the fourth side 111D is connected between the first side 111A and the second side 111B, and the first side 111A, the second side 111B, the third side 111C and the fourth side 111D collaboratively constitute a rectangle for example; the number of the at least two slab parts 112 is four, the four slab parts 112 is a first slab part 112A, a second slab part 112B, a third slab part 112C and a fourth slab part 112D, and the first slab part 112A, the second slab part 112B, the third slab part 112C and the fourth slab part 112D respectively extend outward from the first side 111A, the second side 111B, the third side 111C and the fourth side 111D of the body 111. One end part (without reference numbers) of each of the first slab part 112A, the second slab part 112B, the third slab part 112C and the fourth slab part 112D extends outward, and the other end part (without reference numbers) of each of the first slab part 112A, the second slab part 112B, the third slab part 112C and the fourth slab part 112D is connected to the body 111, and the entire end parts of the first slab part 112A, the second slab part 112B, the third slab part 112C and the fourth slab part 112D extending outward are separate from one another.

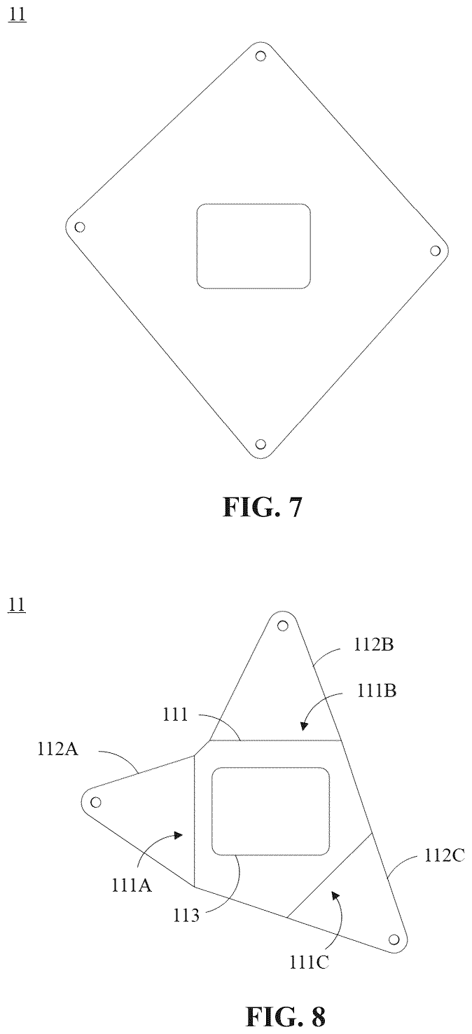

Please refer to FIG. 7, which is the third embodied aspect in the shape of the elastic component 11. As shown in FIG. 7, the third embodied aspect in the shape of the elastic component 11 is similar to the second embodied aspect in the shape of the elastic component 11 (as shown in FIG. 6), but there are differences between the third embodied aspect in the shape of the elastic component 11 and the second embodied aspect in the shape of the elastic component 11: the first slab part 112A, the second slab part 112B, the third slab part 112C and the fourth slab part 112D further extend toward one another and are connected with one another to be an integrated structure.

Please refer to FIG. 8, which is the fourth embodied aspect in the shape of the elastic component 11. As shown in FIG. 8, the fourth embodied aspect in the shape of the elastic component 11 is similar to the first embodied aspect in the shape of the elastic component 11 (as shown in FIG. 5), but there are differences between the fourth embodied aspect in the shape of the elastic component 11 and the first embodied aspect in the shape of the elastic component 11: the two sides of the body 111 are a first side 111A and a second side 111B, and the body 111 further has a third side 111C, wherein the first side 111A, the second side 111B and the third side 111C are or are not adjacently connected with one another; the number of the at least two slab parts 112 is three, the three slab parts 112 is a first slab part 112A, a second slab part 112B, a third slab part 112C, wherein the first slab part 112A, the second slab part 112B and the third slab part 112C respectively extend outward from the first side 111A, the second side 111B and the third side 111C of the body 111. One end part (without reference numbers) of each of the first slab part 112A, the second slab part 112B and the third slab part 112C extends outward, and the other end part (without reference numbers) of each of the first slab part 112A, the second slab part 112B and the third slab part 112C is connected to the body 111, and the entire end parts of the first slab part 112A, the second slab part 112B and the third slab part 112C extending outward are separate from one another.

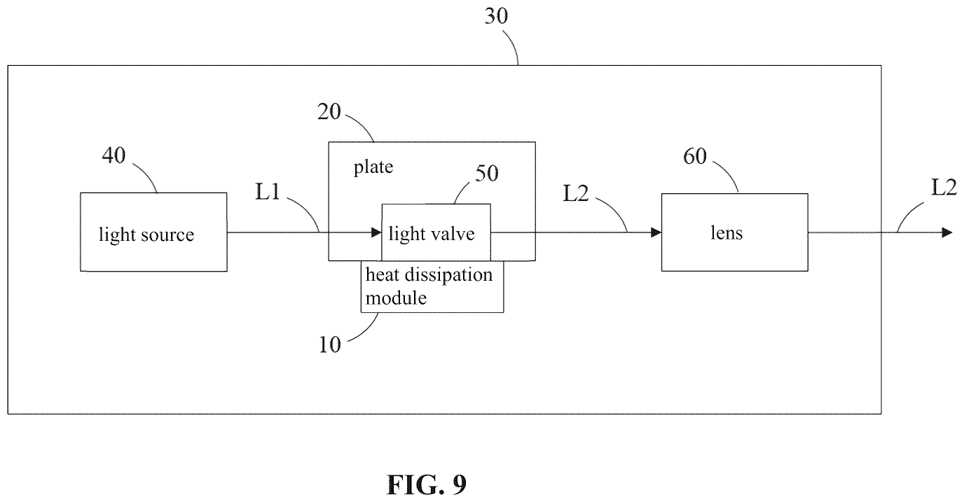

Based on the foregoing embodiment of the present disclosure, a projection device 30 utilizing the heat dissipation module 10 may be further provided. Please refer to FIG. 9, wherein the projection device 30 includes the light source 40, the light valve 50, a lens 60, the foregoing plate 20 and one of the heat dissipation modules 10 of the foregoing embodiments. The light source 40 is configured to provide an illumination light beam L1. The light valve 50 is disposed on the travel path of the illumination light beam L1 and is configured to convert the illumination light beam L1 into an image light beam L2. The lens 60 is disposed on the travel path of the image light beam L2 and is configured to project the image light beam L2. The plate 20 is connected to the light valve 50. The heat dissipation module 10 is fixed on the plate 20. For example, the light source 40 may be the foregoing LD, the foregoing LED or the combination thereof; the light valve 50 may be a reflective-type optical modulator such as the foregoing DMD or a liquid crystal on silicon panel (LCoS panel) or a transmission-type optical modulator such as a transparent liquid crystal panel, an electro-optical modulator, a magneto-optic modulator or an acousto-optic modulator (AOM); the plate 20 is a well-known circuit board; the lens 60 is the combination of one or more lenses with diopters, such as the various combinations of spherical lenses such as a bi-concave lens, a bi-convex lens, a concave-convex lens, a convex-concave lens, a plano-convex lens and a plano-concave lens. The foregoing descriptions are exemplary, but the present disclosure is not limited thereto.

In view of the above description, the embodiments of the present disclosure has at least one advantages as follows. In the embodiments of the present disclosure, the body of the elastic component is disposed under the heat conduction component, and when the elastic component lies in the mounted state, the at least two slab parts of the elastic component would be fixed to the heat dissipation component and are located between the heat dissipation component and the plate, and each of the at least two slab parts provides the body with elastic force toward the heat conduction component. In addition, the orthographic projection of the body of the elastic component on the TEC chip overlaps the first surface of the TEC chip, and the area of the orthographic projection of the body of the elastic component on the TEC chip is less than or equal to the area of the first surface of the TEC chip; hence, the elastic force which is generated from the body is applied to the inner side of the TEC chip. Accordingly, compressing the side of the TEC chip to crack is avoided, thereby realizing the effect of elevating the heat dissipation of the heat dissipation module.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A heat dissipation module configured to be fixed on a plate comprising:
an elastic component comprising a body and at least two slab parts respectively located on two sides of the body, wherein the at least two slab parts extend outward from the body;
a heat conduction component disposed on the body of the elastic component;
a TEC chip with a first surface and a second surface which are located on opposite sides of the TEC chip, wherein the first surface of the TEC chip is thermally connected on the heat conduction component; and
a heat dissipation component thermally connected on the second surface of the TEC chip and fixed to the at least two slab parts of the elastic component;
wherein orthographic projection of the body of the elastic component on the TEC chip overlaps the first surface of the TEC chip, and an area of the orthographic projection of the body of the elastic component on the TEC chip is less than or equal to an area of the first surface of the TEC chip;
wherein the elastic component, the heat conduction component, the TEC chip and the heat dissipation component are sequentially mounted along a mounting direction so that the elastic component lies in a mounted state, and when the elastic component lies in the mounted state, each of the at least two slab parts of the elastic component provides the body with elastic force toward the heat conduction component.

2. The heat dissipation module according to claim 1, wherein the first surface of the TEC chip is a cold side surface, the second surface of the TEC chip is a hot side surface, the heat conduction component is thermally connected to the cold side surface, and the heat dissipation component is thermally connected to the hot side surface.

3. The heat dissipation module according to claim 1, wherein when the elastic component lies in a non-mounted state, the at least two slab parts extend outward from the two sides of the body respectively and slant or bend in the direction far away from the heat conduction component.

4. The heat dissipation module according to claim 3, wherein the two sides of the body is a first side and a second side which are opposite to each other, the at least two slab parts comprises a first slab part and a second slab part, and the first slab part and the second slab part respectively extend outward from the first side of the body and the second side of the body.

5. The heat dissipation module according to claim 4, wherein the body further has a third side and a fourth side which are opposite to each other, the third side is connected between the first side and the second side, the fourth side is connected between the first side and the second side, the number of the at least two slab parts is four, the four slab parts is the first slab part, the second slab part, a third slab part and a fourth slab part, and the first slab part, the second slab part, the third slab part and the fourth slab part respectively extend outward from the first side of the body, the second side of the body, the third side of the body and the fourth side of the body.

6. The heat dissipation module according to claim 5, wherein the first slab part, the second slab part, the third slab part and the fourth slab part are connected to each other.

7. The heat dissipation module according to claim 3, wherein the two sides of the body is a first side and a second side, the body further has a third side, the number of the at least two slab parts is three, and the three slab parts respectively extend outward from the first side of the body, the second side of the body and the third side of the body.

8. The heat dissipation module according to claim 3, wherein the heat dissipation module comprises at least two securing components, each of the at least two slab parts has an end part far away from the body, and when the end parts of the at least two slab parts are fastened to the heat dissipation component by the at least two securing components, the elastic component transforms from the non-mounted state to the mounted state.

9. The heat dissipation module according to claim 1, wherein the elastic component has an opening passing through the body, the heat conduction component has a protrusion, and when the elastic component, the heat conduction component, the TEC chip and the heat dissipation component are sequentially mounted along the mounting direction, the protrusion passes through the opening to be thermally connected to a heat generating component disposed on the plate.

10. A projection device comprising:
a light source configured to provide an illumination light beam;
a light valve disposed on a travel path of the illumination light beam and configured to convert the illumination light beam into an image light beam;
a lens disposed on a travel path of the image light beam and configured to project the image light beam;
a plate connected to the light valve;
a heat dissipation module configured to be fixed on the plate and comprising:
an elastic component comprising a body and at least two slab parts respectively located on two sides of the body, wherein the at least two slab parts extend outward from the body;
a heat conduction component disposed on the body of the elastic component and connected to the light valve;
a TEC chip with a first surface and a second surface which are located on opposite sides of the TEC chip, wherein the first surface of the TEC chip is thermally connected on the heat conduction component; and
a heat dissipation component thermally connected on the second surface of the TEC chip and fixed to the at least two slab parts of the elastic component;
wherein orthographic projection of the body of the elastic component on the TEC chip overlaps the first surface of the TEC chip, and an area of the orthographic projection of the body of the elastic component on the TEC chip is less than or equal to an area of the first surface of the TEC chip;
wherein the elastic component, the heat conduction component, the TEC chip and the heat dissipation component are sequentially mounted along a mounting direction so that the elastic component lies in a mounted state, and when the elastic component lies in the mounted state, each of the at least two slab parts of the elastic component provides the body with elastic force toward the heat conduction component.

11. The projection device according to claim 10, wherein the first surface of the TEC chip is a cold side surface, the second surface of the TEC chip is a hot side surface, the heat conduction component is thermally connected to the cold side surface, and the heat dissipation component is thermally connected to the hot side surface.

12. The projection device according to claim 10, wherein when the elastic component lies in a non-mounted state, the at least two slab parts extend outward from the two sides of the body respectively and slant or bend in the direction far away from the heat conduction component.

13. The projection device according to claim 12, wherein the two sides of the body is a first side and a second side which are opposite to each other, the at least two slab parts comprises a first slab part and a second slab part, and the first slab part and the second slab part respectively extend outward from the first side of the body and the second side of the body.

14. The projection device according to claim 13, wherein the body further has a third side and a fourth side which are opposite to each other, the third side is connected between the first side and the second side, the fourth side is connected between the first side and the second side, the number of the at least two slab parts is four, the four slab parts is the first slab part, the second slab part, a third slab part and a fourth slab part, and the first slab part, the second slab part, the third slab part and the fourth slab part respectively extend outward from the first side of the body, the second side of the body, the third side of the body and the fourth side of the body.

15. The projection device according to claim 14, wherein the first slab part, the second slab part, the third slab part and the fourth slab part are connected to each other.

16. The projection device according to claim 12, wherein the two sides of the body is a first side and a second side, the body further has a third side, the number of the at least two slab parts is three, and the three slab parts respectively extend outward from the first side of the body, the second side of the body and the third side of the body.

17. The projection device according to claim 12, wherein the heat dissipation module comprises at least two securing components, each of the at least two slab parts has an end part far away from the body, and when the end parts of the at least two slab parts are fastened to the heat dissipation component by the at least two securing components, the elastic component transforms from the non-mounted state to the mounted state.

18. The projection device according to claim 10, wherein the elastic component has an opening passing through the body, the heat conduction component has a protrusion, and when the elastic component, the heat conduction component, the TEC chip and the heat dissipation component are sequentially mounted along the mounting direction, the protrusion passes through the opening to be thermally connected to a heat generating component on the plate.
